(19) United States
(12) Patent Application Publication
(10) Pub. No.: US 2019/0107502 A1
(43) Pub. Date: Apr. 11, 2019

(54) Pixel for Thermal Transport and Electrical Impedance Sensing

(71) Applicant: William N. Carr, Raleigh, NC (US)

(72) Inventor: William N. Carr, Raleigh, NC (US)

(21) Appl. No.: 15/727,249

(22) Filed: Oct. 6, 2017

(51) Int. Cl. G01N 27/18; G01N 27/12; G01N 25/18; G01N 27/22; G01N 27/414

(52) U.S. Cl. CPC G01N 27/18; G01N 27/125; H01L 27/16; G01N 27/22; G01N 27/4141; G01N 25/18

(57) ABSTRACT

A thermal pixel is comprised of a micro-platform and includes a plurality of nanowires physically configured to reduce thermal conductivity. A sensing structure is comprised of thermal elements wherein the thermal impedance, electrical impedance or both are modulated upon exposure to a gas or vapor. Thermal elements physically configured on the micro-platform in embodiments include variously a resistive heater, a Seebeck sensor, a Peltier cooler and a thermistor.

### STATEMENT OF RELATED CASES

The case is a continuation-in-part of U.S. Pat. No. 9,236,552 filed on Apr. 2, 2015 and U.S. Pat. No. 9,722,165 filed Mar. 29, 2016. This case claims priority to U.S. Provisional Patent Application 61/808,461 filed on Apr. 4, 2013, and U.S. Provisional Patent Application 61/948,877 filed on Mar. 6, 2014. This case claims priority to US Patent Application 2016/0054179 filed Oct. 14, 2014 and U.S. patent application Ser. No. 14/245,598 filed on Apr. 4, 2014. These cases are incorporated herein by reference.

If there are any contradictions or inconsistencies in language between this application and the cases that have been incorporated by reference that might affect the interpretation of the claims in this case, these related claims should be interpreted to be consistent with the language in this case.

### FIELD OF THE INVENTION

This invention relates generally to a nanostructured thermal pixel structured to provide a sensor for a gas or vapor analyte.

### BACKGROUND OF THE INVENTION

Gas and vapor sensors comprised of a micro-platform wherein readout is based on sensing of an electrical impedance of a sensing element have been demonstrated with several configurations in prior art. One type of these sensors comprises a temperature sensing element wherein its temperature is affected by exposure to an analyte of interest. In this type of sensor, the temperature of a thermal sensing element is modulated variously by a chemical reaction, thermal transport, or a controlled physical property of the sensing element exposed to an analyte of interest. In another gas and vapor sensor having a micro-platform, the transient temperature response of the sensing element over an interval of time provides a means or identifying or monitoring an exposed gas or vapor.

There is a need for micro-platforms supported by and electrically-connected with structures having reduced thermal conductivity. Specific configurations for micro-platforms having increased thermal isolation from a surrounding platform are needed to make possible thermal sensors of significantly improved sensitivity and also to provide pixel sensor functions not hitherto practical.

Phononic structures have been demonstrated to reduce the thermal conductivity of thin slabs of material, especially semiconductor thin films. Films of slab material and nanowires, physically configured with phononic scattering and/or phononic resonant structures for reducing thermal conductivity, are disclosed in the following prior art.

S. Mohammadi et all, Appl. Phys. Lett., vol. 92, (2008) 221905 discloses a silicon slab having 8 layers of phononic crystal (PnC) comprising a plurality structure wherein the transport of thermal phonons of a frequency within the phononic bandgap is blocked.

Olsson et al U.S. Pat. No. 7,836,566 (2010) discloses a microfabricated slab comprised of a multi-dimensional periodic array of phononic structures embedded in a silicon semiconductor matrix providing a phononic crystal (PnC) with a phononic bandgap.

Y. M. Soliman et al Appl. Phys. Lett., vol. 97, (2010) 193502 discloses a slab of silicon comprised of solid pillars and plugs configured as PnCs to obtain phononic bandgaps, the bandgaps defining frequency bands wherein the propagation of acoustic waves is forbidden.

M Ziaci-Moayyed et al, Proc. IEEE 24^{th} Int'l Conf on MEMS (2011), pp. 1377-1381. discloses a semiconductor thin film physically configured with Bragg-type and Mie-type PnC reflecting mirrors to reduce thermal conductivity. The periodic array of scattering inclusions in embodiments comprises 7-layers. The PnC design causes certain frequencies of the phononic thermal energy transport to be completely reflected by the PnC.

I. El-Kady et al, in U.S. Pat. No. 8,508,370 (2013) discloses a PnC slab configured to provide a phononic bandgap insulator that reduces thermal conductivity. The slab is comprised of a periodic array of scattering inclusions embedded in a host matrix. PnCs having a plurality of layers of PnC crystals are disclosed as both stacked layers and layers staged side-by-side.

El-Kady et al in U.S. Pat. No. 8,094,023 (2012) discloses a PnC device comprised of a cascade of phononic crystal layers. In this device, the superposition of Mie phononic resonance response and a Bragg phononic condition response result in opening of phononic frequency gaps wherein phonons are forbidden to propagate.

Y. Zhao et al, “Engineering the thermal conductivity along an individual silicon nanowire by selective helium ion irradiation,” Nature Communications, vol. 8 (2017) 15919 discloses a Si-nanowire wherein thermal conductivity is reduced with He ion implanting at various positions along the length of the nanowire.

U.S. Pat. No. 9,291,297 and continuing applications of P. G. Allen et al disclose a thermal insulator comprised of multiple layers of PnCs having a phononic bandgap wherein heat transporting phonons within a selected range of frequencies are substantially blocked by each PnC crystal layer.

A micro-platform operated as a sensor with increased thermal isolation from a surrounding support platform is disclosed in U.S. Pat. Nos. 9,236,552 and 9,722,165. These two patents disclose micro-platforms supported by phononic nanowires, wherein the nanowires are comprised of semiconductor material having structure that reduces thermal conductivity.

There is a need for gas and vapor sensors physically configured with dimensions at microscale and nanoscale providing further advantages of increased sensitivity, additional dynamic range, differentiation for multiple analytes, reduced footprint size, reduced power consumption, and miniaturization.

### SUMMARY OF THE INVENTION

The present invention provides a pixel for thermal transport and electrical impedance sensing.

This invention provides a pixel with advantages over prior art including improved performance and functionality, low cost manufacturing, small size and ease of miniaturization, flexibility in mass production, simple operation and compatibility with nanotechnology foundry tools.

The salient elements of the pixel include:

A thermal pixel comprised of a micro-platform supported by a plurality of nanowires, wherein each nanowire is partially disposed on both the micro-platform and an off-platform substrate region, the off-platform substrate region surrounding the micro-platform, and the pixel further comprised of a sensing structure having at least one thermal element, wherein the at least one thermal element is disposed on the micro-platform and exposed to a gas or vapor analyte, and further wherein:
one or more of the plurality of nanowires is physically configured with one or more first layers, the first layers comprised of phononic scattering nanostructures and/or phononic resonant nanostructures, the nanostructures providing a reduction in the ratio of thermal conductivity to electrical conductivity;
the one or more of the plurality of nanowires provides a reduction in the mean free path for at least some heat conducting phonons;
the electrical impedance of the at least one thermal element is affected by exposure with the analyte, and
the thermal pixel provides a means for identifying and/or monitoring one or more chemical or physical characteristics of the analyte.

Thermal elements may be active or passive. An active thermal element provides a source of heat or a cooling heat sink affecting the micro-platform temperature. An active thermal element may be comprised of resistive heater, a Peltier thermoelectric cooler, or a mesh of nanosheets or nanotubes or a material providing an exothermic chemical reaction. An example of the exothermic active element is the Pd catalytic Pd active element within a pellistor which self-heats upon exposure to a flammable volatile organic carbon analyte. At least one thermal element is a temperature sensor without any internal heating or cooling mechanisms. Examples of the passive temperature sensor in the present invention include a thermistor, a Seebeck thermoelectric element, a mesh of nanotubes and a MOSFET.

The present invention provides a thermally isolated pixel comprising a structure for sensing one or more of chemical reactions and thermal transport of a gas or vapor analyte. A thermal sensor structure is provided which monitors a thermal impedance and/or electrical impedance between or within thermal elements of the pixel. In embodiments, the present invention provides a pixel with a thermally-isolated micro-platform and a sensing structure for identification and/or sensing a physical parameter of an analyte. In embodiments, the thermal heat transfer from a heater element through an analyte is monitored to provide a sensor for analyte pressure, wind speed and humidity. In embodiments, a doping reaction and other chemical reactions are monitored by sensing the electrical impedance of a chemi-resistor sensor.

In some embodiments, an analyte is catalytically converted within a chem-FET into atomic hydrogen (Ha) to provide a dipole of charge within or on the gate dielectric of a MOSFET transistor. In the chem-FET sensor embodiment, the electrical impedance of the diode-connected transistor changes upon exposure to an analyte. In other embodiments, heat transport from an exothermic reaction as with a pellistor is monitored to provide a sensor function which is monitored by a temperature sensor of high sensitivity disposed on the micro-platform.

In some embodiments, the thermally-isolated micro-platform is heated to outgas and evaporate residues from an exposing analyte thereby providing a reset of the sensor to a reference condition. In other embodiments, the micro-platform is heated to provide a reset or initialization of a passive sensor as with a chem-FET sensor.

In most embodiments, the micro-platform provides an isothermal structure. In many embodiments, resistive and thermoelectric elements are electrically isolated from the micro-platform and a surrounding off-platform area with a dielectric film. In other embodiments, adequate electrical isolation within and without a thermal element is provided by a device layer of high resistivity. In yet other embodiments, electrical isolation between thermal elements disposed on a micro-platform is provided by an electrostatic shield.

In embodiments, a single thermal structure may be operated as both an active thermal element and a passive thermal element. In embodiments, of the present invention, the heater is an active thermal element comprised of a metal film or a semiconductor.

The metal films of this invention are typically comprised of one or more of ALD films including W, NiCr, Pd, Ti, Cu, Pt, Mo and Al of nanometer thickness with an underlying ALD adhesion enhancer such as Ti or Cr. In embodiments, the semiconductor thermal elements comprising thin films are selected from one or more of a group including silicon, germanium, silicon-germanium, gallium arsenide, gallium nitride, indium phosphide, silicon carbide, Bi₂Te₃, Bi₂Se₃, CoSb₃, Sb₂Te₄, La₃Te₄ ZnS, CdS, SnSe, and alloys thereof. In other embodiments, a thermal element is comprised of a sheet or rolled sheets of graphene or nanotubes of various materials. The passive thermal element may be comprised of one or more of a thermistor, Seebeck thermocouple, bandgap diode, MOSFET and bipolar transistor. Any of the above mentioned metal films, semiconductor films including nanotube structures and devices may comprise a thermal element.

In embodiments, the active thermal element and the passive thermal element may comprise the same element. For example, a tungsten ALD film, operated as an active heater thermal element and driven by a current source, may also be operated simultaneously as a passive thermister thermal element wherein voltage across the thermistor is monitored.

In embodiments, signal conditioning, processing and control circuits are disposed within the pixel. In other embodiments, these circuits are located external to the pixel. The pixel sensor structure typically monitored and controlled one or more of a voltmeter, ohmmeter, capacitance meter, constant current source, potentiostat, and a full- or half-Wheatstone bridge.

A method for identifying and/or monitoring a gas or vapor analyte comprises steps wherein first measurements obtained with a reference analyte for calibration purposes is compared with second measurements obtained with an analyte of interest. Processing of the first and second measurements provides a method for identification and/or monitoring of the gas or vapor analyte of interest.

In some embodiments, the passive thermal element is a Seebeck thermoelectric device which monitors the micro-platform temperature controlled by thermal coupling from an active heater thermal element. The Seebeck thermoelectric device is comprised of two junctions including a hot junction and a cold junction disposed at the ends of semiconductor nanowires wherein the nanowires provide a physical support connection between a surrounding off-platform substrate region and the micro-platform. The Seebeck device generates a voltage proportional to the temperature difference between the on-platform junction and the off-platform junctions.

The pixel, in embodiments, is comprised of an electrical connection between on- and off-platform circuits through nanowires. The thermal diffusivity within the micro-platform structure is large enough in most embodiments to provide a single isothermal reference point for temperature across the micro-platform. The thermal heat capacity of the micro-platform and the thermal conductivity of the nanowires is designed to provide a thermal time constant with respect to the off-platform area for platform thermal transients that can vary typically from microseconds to seconds.

In embodiments, a differential temperature across a thermocouple formed of supporting nanowires provides a thermal element for sensing the micro-platform temperature. The thermocouple is a thermoelectric device providing a voltage source based on the Seebeck effect. When current flow through the thermoelectric device is sourced externally, the same thermoelectric device may be operated as a Peltier cooling device. Seebeck and Peltier effects are thermodynamically reversible phenomena. In embodiments, a Seebeck temperature sensor and a Peltier cooler may comprise the same thermoelectric device.

In some embodiments, an array of nanowires are configured as thermoelectric devices and operated in the Peltier mode as an active cooling thermal element to cool the micro-platform. In embodiments, nanowires are configured as Peltier thermal elements and operated with a platform temperature sensor to provide a means of dynamic, real-time control of the micro-platform temperature through connections with external closed loop circuits.

Thermoelectric devices comprised of only one pair of nanowire elements generally do not provide an adequate response for Seebeck and Peltier applications of this invention. In embodiments, an array of thermoelectric devices may be physically configured with as many as 3,000 on-platform junctions. Thermoelectric devices are connected in series or combinations of series/parallel configurations to provide a convenient or optimum electrical impedance match with signal conditioning or power sourcing circuitry.

The starting wafer for pixel fabrication in embodiments is a sandwich semiconductor-on-insulator (SOI) wafer. The SOI wafer is comprised of a first device layer of appropriate semiconductor with electrical and thermal conductivity, a sandwiched dielectric, and an underlying off-platform substrate. In exemplary embodiments of this invention, the SOI starting wafer is comprised of silicon. It is a sandwich comprised of a thin single crystal silicon device layer, a thin silicon dioxide layer and a silicon handle substrate.

All embodiments of the present invention are comprised of a plurality of nanowires physically configured with one or more first layers having phononic scattering and/or resonant structures. In this invention, the dominant mechanisms effecting phonon mean free path in nanowires are based on Umklapp scattering, boundary scattering including reflections and resonance processes. In embodiments, a reduction in thermal conductivity provided by a specific phononic structure may involve both scattering and resonance phenomena.

In embodiments, surface structure, including patterned surface nanodots, can exert a significant influence on boundary scattering and reduce thermal conductivity. Phononic scattering structures within the nanowire may also be provided by molecular aggregates and implanted atomic species within a nanowire structure. In other embodiments, phononic structuring is obtained with holes disposed at random or within a periodic structure within a nanowire. Phononic scattering structures can be disposed as random arrays in or on the nanowire. The effective mean free path for heat conducting phonons is dependent on the particle-like relaxation time due to multiple scattering of the corpuscular phonons at atomic scale. The effectiveness of phononic structures comprised of one or more first layers, providing a reduction of thermal conductivity, is a result of material engineering based on the duality principle in quantum mechanics which stipulates that a phonon can exhibit both wave- and particle-like properties at small scales.

Thin films of semiconductor have been physically configured to provide a phononic crystal insulator with a phononic bandgap (see for example, S. Mohammadi et all, Appl. Phys. Lett., vol. 92, (2008) 221905). In some embodiments, wherein thermal conductivity of a nanowire is reduced, an array of phononic structures disposed within or on the surface of a nanowire, provide layers of phononic crystal (PnC). Phononic crystal structuring requires a periodic array of structures such as holes which exhibit elastic (phonon) band gaps. Phononic bandgaps of PnCs define frequency bands where the propagation of heat-conducting phonons is forbidden. Phonon scattering within a PnC-structured nanowire is obtained by physically configuring the nanowire to reduce the phononic Brillouin zone and in some embodiments extend scattering to include successive PnC arrayed layers or interfaces. Nanowires configured with PnC structures can enhance both incoherent and coherent scattering of heat conducting phonons. PnC structures can provide a Bragg and/or Mie resonance of heat conducting phonons.

Bragg resonant structures in embodiments comprise phonon transport between scattering structures such as particulates, pillars, and holes. In embodiments, Bragg resonant structures can also be provided in silicon nanowires by implanted elements such as Ar and Ge. Mie resonant structures comprise phonon transport within structures including holes, indentations and cavities within a first nanowire layer. (see M. Ziaci-Moayyed, et al “Phononic Crystal Cavities for Micromechanical Resonators”, Proc. IEEE 24^{th} Intl Conf. on MEMS, pp. 1377-1381, (2011).

An aspect of the present invention is the physical nanowire adaptation providing phononic scattering and/or resonant structures to reduce the mean free path for thermal energy transport by phonons. This provides a reduction in thermal conductivity. Furthermore, the dimensions of phononic scattering structures are configured to not limit the scattering range for electrons and thereby have minimal effect on the bulk electrical conductivity of the nanowire. In this invention, a first nanowire layer is comprised of a semiconductor where the difference in mean free path for phonons and electrons is significant. Typically, in embodiments, the semiconductor nanowires will have electron mean free paths ranging from less than 1 nm up to 10 nm. The mean free path for phonons that dominate the thermal transport within the nanowire of the present invention is within the range 20 to 2000 nm, significantly larger than for electrons. Phononic structuring of a first layer of nanowires reduces thermal conductivity and has less effect on the electrical conductivity.

In embodiments, the desired phononic scattering and/or resonant structures within nanowires may be created as one or more of randomly disposed and/or periodic arrays of holes, pillars, plugs, cavities, surface structures, implanted elemental species, and embedded particulates. In embodiments, the phononic structuring may comprise patterned surface structures comprised of quantum dots. This structuring, in embodiments, comprises a first layer of nanowires reducing the thermal conductivity.

In some embodiments, the one or more phononic layers of a nanowire is created based on an electrochemical or multisource evaporation process for a semiconductor film deposition and subsequent annealing to provide a porous or particulate-structured film. In other embodiments, a nanowire is selectively ion implanted with a species such as Ar to provide scattering structures. Processes for the synthesis of thin films of nanometer thickness with porous, particulate or surface structures, both with and without lithography, is well known to those familiar with the art.

In embodiments, the one or more nanowire first layers is a semiconductor selected from a group including silicon, germanium, silicon-germanium, titanium oxide, zinc oxide, gallium arsenide, gallium nitride, indium phosphide, silicon carbide, sheets of graphene, nanotubes of carbon and other materials and alloys thereof.

In embodiments wherein an increased thermoelectric efficiency is needed, the nanowire first layer is a semiconductor selected from a group including Bi₂Te₃, BiSe₃, CoSb₃, Sb₂Te₃, La₃Te₄, SnSe, ZnS, CdS and alloys thereof.

In embodiments, the nanowire is configured of a sandwich structure comprised of a second layer. This second layer is a metal of nanometer thickness selected from a group including Pt, W. Pd, Cu, Ti, NiCr, Mo and Al providing an increased electrical conductivity. The second layer may be patterned as a film continuing through the nanowire and onto the micro-platform. In embodiments, the second layer of metal connect further onto the micro-platform to provide a thermal element.

In embodiments, a nanowire is a sandwich structure comprised of a third layer of a dielectric material selected from one or more of silicon nitride, silicon oxynitride, aluminum oxide, and silicon dioxide to provide electrical isolation and/or a reduction in mechanical stress. The third layer may extend beyond the nanowire and over the micro-platform providing a biaxial compensating stress, often a tensile stress, to reduce overall stress across the micro-platform. In embodiments, the third layer of dielectric material may be disposed between the first and second layers. In embodiments, the third layer may be disposed onto a second layer. In embodiments, the third layer may be disposed directly on the first layer.

In embodiments, the pixel is comprised of multiple micro-platforms. A separate micro-platform may provide a reference sensor not exposed to the analyte. A separate micro-platform may be configured to provide different types of sensors and sensors sensitive to additional analytes. The pixel physically configured with multiple platforms may provide, for example, a simultaneous static and dynamic sensing of the same analyte.

In the exemplary embodiments of this invention, the starting wafer is a silicon sandwich structured as a semiconductor-on-insulator (SOI) wafer. The SOI wafer is comprised of a first semiconductor device layer of appropriate electrical conductivity, a sandwiched silicon dioxide film (BOX) of low electrical conductivity, and an underlying silicon handle substrate. The SOI starting wafer is typically manufactured by processes such as BESOI and SMARTCUT™. The SOI wafer is processed using industry semiconductor manufacturing wafer processes and processing tools including CVD, PVD including co-evaporation, MOCVD, RTP, RIE, DRIE, annealing/diffusion furnaces, ion implantation, deep submicron EBL and lithography steppers familiar to those of ordinary skill in the art. Processing of the pixel active silicon layer may include fabrication of integrated circuits, especially CMOS circuits, disposed on or off the micro-platform. Final processing steps include release of the micro-platform using a backside or frontside etch and wafer dicing. Other final process steps in pixel fabrication may include growth or placement of sheet graphene and nanotubes of selected materials including CNTs in various formats onto the micro-platform to provide chemi-resistive functions.

Specialized wafer handler cassettes, designed to protect wafers with fragile micro-platform structures are used as necessary. To package the pixel after it is processed at wafer scale, dicing techniques are used which do not damage the micro-platform and nanowire. For example, dicing can be performed using a CO₂ laser scribe operated to minimize ablation.

In some embodiments, the pixel header is configured to provide a window of porous material such as a microfilter that permits the analyte gas or vapor to readily diffuse into the header interior and exclude particulates. The porous filter protects the nanowires and micro-platform from damage and unwanted accumulations due to unwanted particulates carried by the analyte.

It is an object of the present invention to provide a thermal pixel comprised of at least one sensor selected from the group consisting of chemi-resistor, chem-FET, capnometer, spirometer, capacitance sensor, miniature weather station, reference calibration sensor, sensor with sensitivity to multiple analytes, and sensor with extended and/or complementing sensitivity range. In some embodiments, the pixel is configured to provide identical sensing elements operated to provide a redundant sensor to enhance an overall reliability or measurement accuracy.

### BRIEF DESCRIPTION OF THE FIGURES

FIG. 1A depicts a plan view of a prior art micro-platform.

FIG. 1B depicts two nanowires comprising a prior art thermoelectric element

FIG. 2A depicts a plan view of a prior art nanowire with exemplary phononic structure.

FIG. 2B depicts a cross-sectional view of a prior art nanowire with exemplary phononic structure.

FIG. 3 depicts a cross-sectional view of a prior art micro-platform and supporting nanowires released with backside etching.

FIG. 4 depicts a cross-sectional view of a prior art micro-platform with nanowires and underlying dielectric film support released with backside etch.

FIG. 5 depicts a cross sectional view of a prior art micro-platform and nanowires released with frontside etch.

FIGS. 6A, 6B and 6C depict cross-sectional views of a nanowire comprised of two, three and four structural thin films in accordance with the present teachings.

FIG. 7 depicts a plan view of a pixel physically configured with a micro-platform in rectangular format comprised of a semiconductor heater and a thermister in accordance with the present teachings.

FIG. 8 depicts a plan view of a pixel physically configured with a micro-platform in rectangular format comprised of thin film metal and semiconductor thermal elements in accordance with the present teachings

FIG. 9 depicts a pixel physically configured with the micro-platform in a rectangular format comprising a thin film metal heater and a thermoelectric thermal element in accordance with the present teachings.

FIG. 10 depicts a pixel physically configured with the micro-platform in a rectangular format with a thermoelectric and a resistive thermal element in accordance with the present teachings.

FIG. 11 depicts a pixel with the micro-platform physically configured in a circular format comprised of a serpentine metal heater in accordance with the present teachings.

FIG. 12 depicts a chem-FET sensor physically configured in a circular format and comprised of a MOSFET in accordance with the present teachings.

FIG. 13 depicts a pixel physically configured in a rectangular format with multiple micro-platforms having resistive thermal elements disposed over a single cavity in accordance with the present teachings.

FIG. 14 depicts a pixel with a single micro-platform physically configured with electrodes providing electrical contact with a mesh of activated sheet graphene or nanotubes functioning as chemi-resistors in accordance with the present teachings.

FIG. 15A depicts a pixel physically configured with a single micro-platform comprised of two thermoelectric thermal elements in accordance with the present teachings.

FIG. 15B depicts a pixel physically configured with a single micro-platform comprised of a thermoelectric and a resistive thermal element in accordance with the present teachings.

FIG. 15C is a graph depicting the rate of Peltier cooling before and after reaching a dew point or frost point temperature.

FIG. 15D depicts a pixel physically configured with a single micro-platform comprised of a thermoelectric thermal element and capacitive electrodes for analyte bulk impedance sensing in accordance with the present teachings.

FIG. 16 depicts a pixel comprised of three micro-platforms providing multiple thermal elements in accordance with the present teachings.

### DETAIL DESCRIPTION

### Definitions

The following terms as explicitly defined for use in this disclosure and the appended claims:

“a specific sensor” such as a “dew point sensor” means the pixel configured as a sensor providing a specific sensor function when operated within an apparatus.

“disposed on” means a structure “physically positioned on” or “created within”. For instance, a resistive thermistor element disposed on a micro-platform may be physically bonded to the micro-platform or it may be created within the micro-platform.

“analyte” means a gas or vapor of interest disposed proximal to and exposed to the sensing structure of a thermal pixel.

“sensing structure” means a structure comprised of one or more thermal elements.

“active thermal element” means a structural thermal element receiving electrical power from an external source or heated internally by an effecting exothermic chemical reaction.

“passive thermal element” means a structural element that operates with minimal external electrical power and is typically a type of temperature sensor including a thermistor or Seebeck thermoelectric element.

“thermal impedance sensing” is a sensing function based on changes in thermal conductivity affecting of a sensing structure when the pixel exposed to an analyte.

“electrical impedance sensing” is a sensing function based on changes in the real or imaginary parts of an electrical impedance of a sensing structure exposed to an analyte. Electrical impedance sensing in embodiments may comprise a thermal impedance sensing function.

“Pirani gauge” means a pressure sensor based on sensing thermal transport into or through an analyte.

“chem-resistive sensor” means a sensor wherein the primary means of transduction is a chemical reaction such as a doping or a loading of a semiconductor effecting changes in the electrical impedance of a thermal element when the pixel is exposed to an analyte.

“chem-FET” means an MOS device physically configured as a sensor wherein the primary means of transduction is modulation of the electrical impedance of the MOS transistor channel by an analyte.

“pellistor” means a type of chemi-resistive sensor used to detect gases which are combustible by monitoring the thermal transport and temperature of a chemical reaction, generally the exothermic formation of water from hydrogen and oxygen.

“capnometer” means a type of chemi-resistive sensor for measuring CO₂ in exhalation.

“mm, um, and nm” as prefixes mean micro- and nano-, respectively, referring to millimeter, micrometer and nanometer dimensions.

“ALD” film means an atomic layer deposition film of thickness generally between 2 and 20 nm.

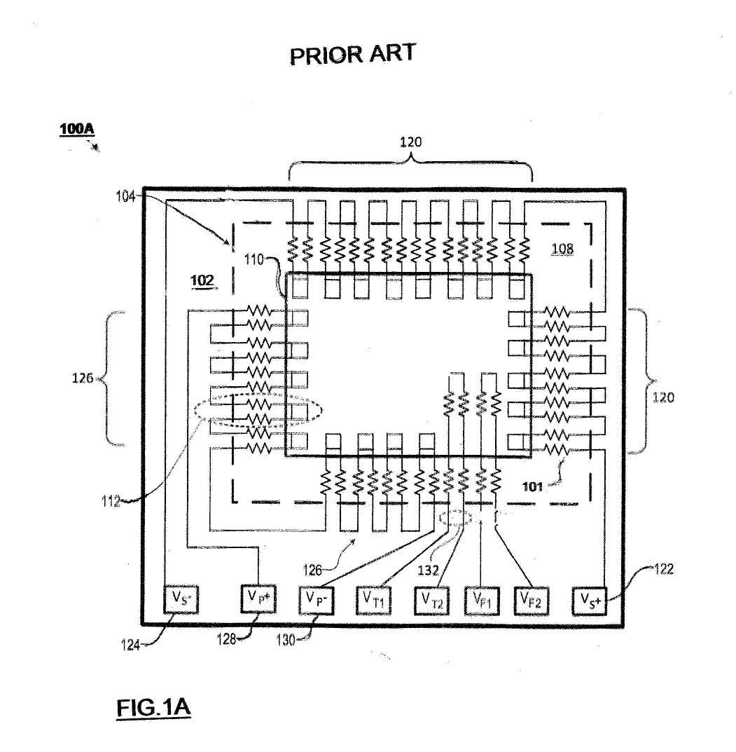

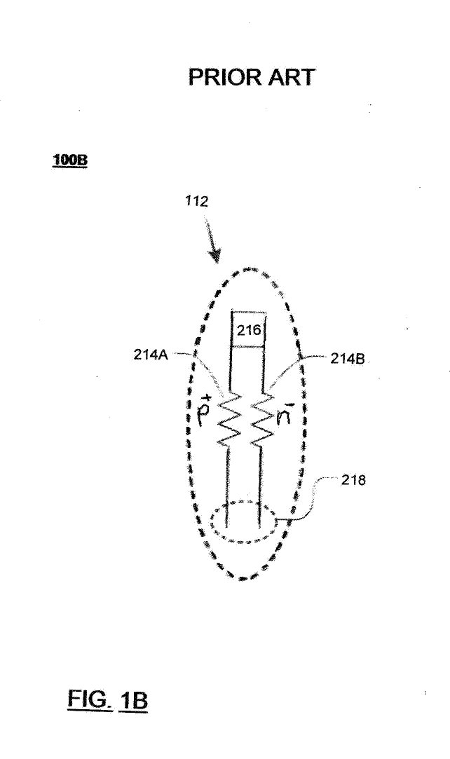

FIG. 1A depicts a plan view of a prior art thermoelectric sensor 100A disclosed in U.S. Pat. No. 9,236,552. The prior art pixel disclosed is comprised of a micro-platform 110 with supporting nanowires 101 disposed over a cavity 108 wherein the cavity is bounded by perimeter 104. The nanowires 101 attached to the micro-platform extend from a surrounding support platform 102. The pixel is comprised of thermoelectric elements 112 connected electrically in series. The connection 132 depicts circuit connections to structures including thermistor resistors and integrated circuits disposed in or on the micro-platform 110. The series-connected array 120 of thermoelectric devices 112 is disposed around the periphery of the micro-platform 110 with connections through nanowires 101 to off-platform bonding pads 122 and 124. A second series-connected array 126 of thermoelectric devices 112 is disposed around the platform 110 with a connection through nanowires to bonding pads 128 and 130.

FIG. 1B depicts thermoelectric element 112 with one junction 216 disposed on the micro-platform 110 and the other two junctions 218 disposed on the off-platform support region 102. The thermoelectric element 112 is comprised of two semiconductor nanowires 101 wherein each thermoelectric element is comprised of a nanowire 214A doped p+ and a nanowire 214B doped n−. Each array 120 and 126 of thermoelectric elements 112 may be operated as a passive Seebeck thermal sensing element or an active Peltier thermal cooler element depending on external circuitry.

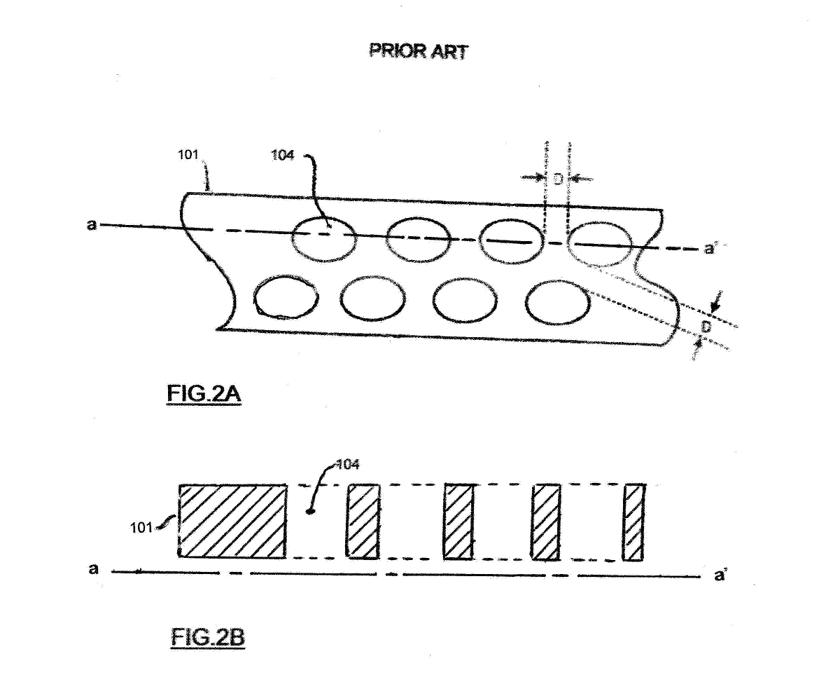

FIG. 2A and FIG. 2B depict an embodiment of prior art nanowires 101 with an exemplary phononic structural embodiment. In this embodiment, the phononic structures are comprised of holes 104 in the thin nanowire 101 film. The holes 104 are separated by a dimension D created to be less than the mean free path for at least some phonons conducting heat along the length of the nanowire 101. FIG. 2B depicts a cross-sectional view of the FIG. 2A prior art nanowire 101 with exemplary phononic structural holes 104. The nanowire 101 is terminated on the micro-platform 110 and the surrounding support platform 102. The prior art phononic structuring of the pixel nanowire 101 reduces the thermal conductivity of the nanowire.

The nanowires 101, in embodiments, are physically configured with a scattering phononic structure created by submicron patterning of the active layer of a silicon SOI starting wafer. In some embodiments, nanowires 101 are physically configured as nanofilms synthesized by depositions including sol gel and multi-source evaporation processes. These synthesis processes use appropriate precursors and specialized thermal annealing to form nanowires with mesoporous or clustered phononic scattering structures

In all embodiments, the thermal conductivity of the nanowire 101 is advantageously reduced by the physical phononic adaptation which has only limited effect on the electrical conductivity.

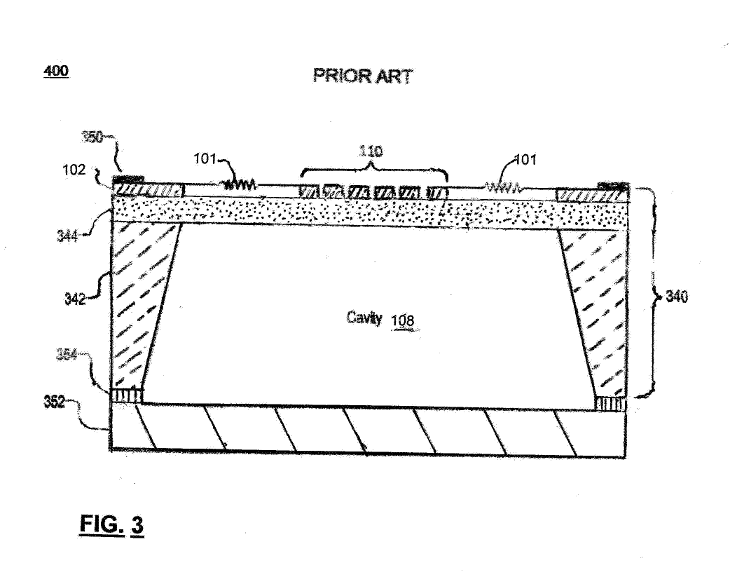

FIGS. 3, 4 and 5 each depict cross-sectional views of the prior art sensor of FIG. 1. The pixel, comprised of levels 340 is processed as from starting wafers. The pixel includes micro-platform 110, nanowires 101, surrounding platform support 102 and the cavity 108 located under the micro-platform and nanowires. A patterned metal film 350 such as Al or Ti—W provides the bonding pad area for external electrical connection through nanowires 101 to elements on the micro-platform 110. In these embodiments, topside structures above the cavity 108 are depicted as released from substrate 342 prior to die bonding the pixel die with adhesion layer 354 to external substrate 352. In these embodiments, the pixel, comprised of levels 340, is processed at wafer level. In these embodiments, platform and nanowire release processing is completed prior to wafer dicing and die bonding. As a post-process step, the pixel die is bonded onto a header substrate 352 with adhesion layer 354.

In the embodiment depicted in FIG. 3, a bottomside silicon wafer etch is used to release releases the micro-platform 110 and nanowires 101 and form cavity 108. Backside etching is obtained with a plasma DRIE or with an anisotropic liquid etchant including EDP, TMAH, KOH or hydrazine. In all FIG. 3 embodiments, the silicon dioxide layer 344 provides an etch stop for the backside etch.

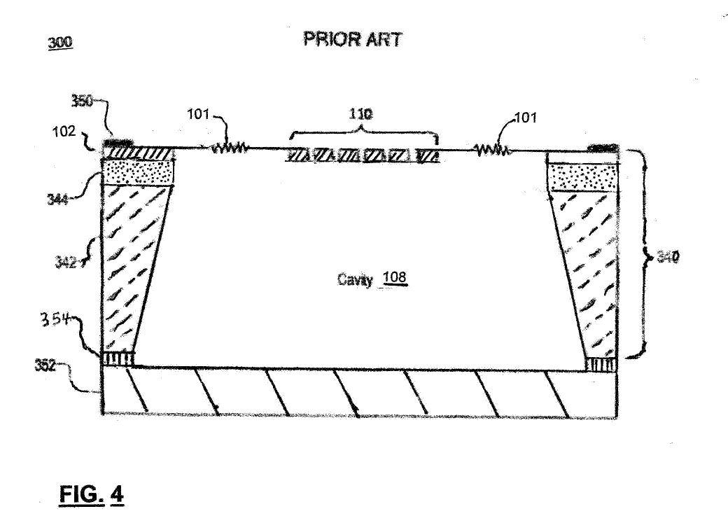

FIG. 4 depicts a cross-sectional view of a prior art micro platform 110 and support structures wherein the backside etch process is initially the same as for the FIG. 3 depiction but with additional processing. Backside etching for the embodiment of FIG. 4 is followed by a bottomside vapor HF etch which removes the oxide layer portion of 344 disposed under the micro-platform 110 and nanowires 101.

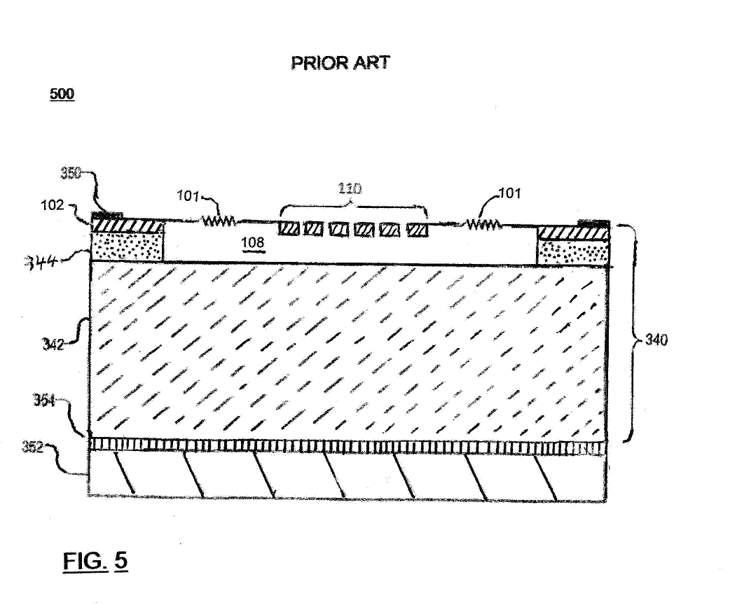

FIG. 5 depicts a cross-sectional view of a prior art pixel using a topside release etch process. Typically, the dielectric BOX layer 344 is silicon dioxide. which is selectively removed from underneath the micro-platform 110 and the nanowires 101 to create cavity 108 using a vapor HF etchant. In this embodiment, topside structures are passivated against the vapor HF etch with a thin protective film such as silicon nitride as appropriate.

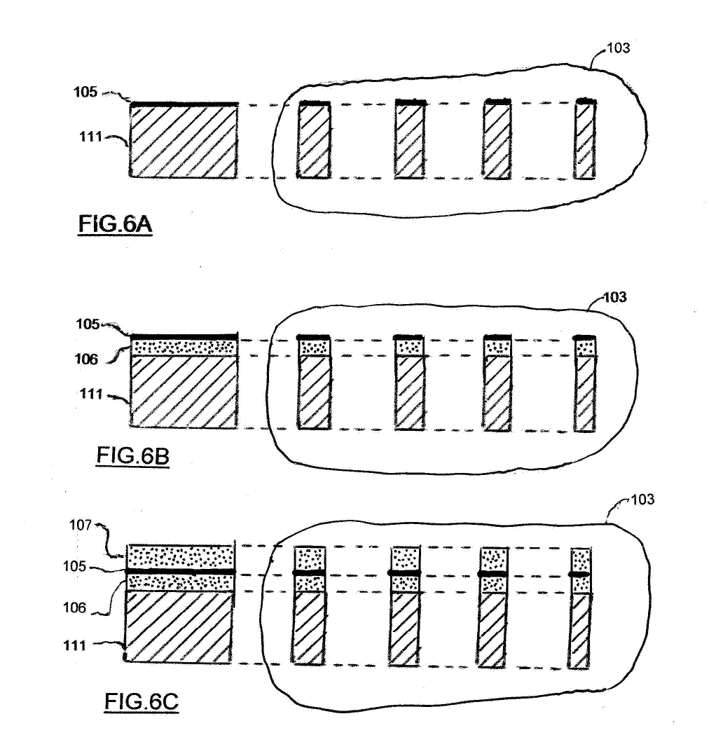

FIGS. 6A, 6B and 6C depict cross-sectional views of the device layer comprised of a nanowire 103 and a termination into an area 111. The nanowire 111 termination area is contained within the surrounding support platform 102. In this illustrative embodiment, phononic scattering or resonant structures are depicted as holes within the area of the nanowire 103. In the exemplary embodiment obtained by processing silicon SOI starting wafers, the holes in the nanowire 103 are created using a DRIE tool with precursors appropriate for the material etched.

The exemplary embodiments of the present invention are structured from a starting wafer of silicon SOI. In embodiments, the active layer of a starting silicon SOI wafer forms both the micro-platform and a layer a nanowire. In these exemplary embodiments, the active layer is itself processed and various additional structural films overlay the active layer.

FIGS. 6A, 6B and 6C of the present invention depict a phononic nanowire physically configured variously with additional topside layers of metal and dielectric films covering a phononic layer 101. The phononic portion of the nanowire is depicted as structure as nanowire 103. FIG. 6A depicts the nanowire phononic structure 103 and surrounding support area 111 physically configured with an overlying metal layer. In embodiments, the metal layer increases the electrical conductivity of the nanowire and is obtained by sputtering or an evaporative deposition process to provide a film, generally an ALD film.

FIG. 6B depicts a nanowire phononic structure 103 and surrounding support area 111 physically configured with a dielectric layer 106 sandwiched between an overlying metal film 105 and the phononic semiconductor layer 101 of the starting wafer. The dielectric layers in some embodiments are Si₃N₄ obtained by a CVD process using NH₃ and SiH₄ as precursors. In another embodiment, the dielectric layer is SiO₂ obtained by using a oxide target with RF sputtering.

FIG. 6C depicts the nanowire phononic structure 103 and surrounding support area 111 structurally configured with an overlying metal film 105 sandwiched between to dielectric films 106 and 107. In embodiments, the dielectric films 106 and 107 provide one or more of electrical insulation, stress relief, and passivation against process etch species.

In all drawings depicting embodiments of this invention, it is understood that portions of the off-platform support area 102 which surround nanowire junctions and interconnects may not be detailed. Areas of the pixel not illustrated may be further processed to electrically-isolate active and passive thermal elements from adjacent areas of layer 102. Selected areas may, for example, be further comprised of patterned silicon nitride to facilitate topside release of a micro-platform. These films and areas are not explicitly identified in all drawings.

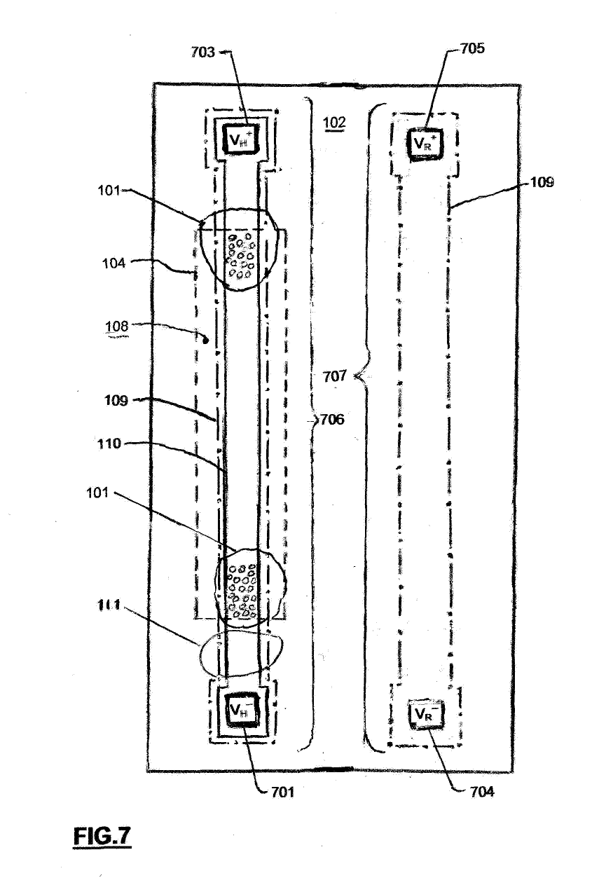

FIG. 7 depicts a plan view of a pixel of the present invention. with an isothermal micro-platform 110 in rectangular format comprised of an exemplary semiconductor thermal element 706 disposed on a micro-platform and passive thermal sensing element 707 disposed on the surrounding support structure 102. In embodiments, thermal element 706 provides both a heater element and a passive thermal thermistor element. Thermister 707 is contacted with bonding pads 704, 705 and is typically obtained with a p-type dopant diffused into area 109 within a high resistivity n-type surrounding platform 102. Thermister 707 is used to monitor the temperature of the surrounding platform support structure 102. The silicon heater element 706 is comprised of a central high temperature micro-platform 110 supported by nanowires 101, surrounding platform support structure areas 111 and electrical contacting metal pads 701 and 703, The heater 706 is released from the underlying cavity 108 using an appropriate etch process. The semiconductor thermal element 706 is selectively diffused with either boron or phosphorus in particular to increase electrical conductivity through the conducting path of the heater between bonding pads 701 and 703. The semiconductor thermal element 706 is electrically isolated from the underlying handle wafer by a dielectric, typically silicon dioxide.

In applications for the pixel depicted in FIG. 7, resistive thermal element 706 is driven by an external current source to heat the micro-platform 110. The voltage measured at the heater terminals 701 and 703 provides a measure of the temperature of the micro-platform 110. The thermistor 707 is connected to an external circuit such as an ohmmeter through contacts 704 and 705 senses the temperature of the surrounding off-platform area 102. The sensor configuration of FIG. 7, in embodiments, provides a combination resistive heater thermal element 706 and a thermistor sensing thermal element 706 within a single pixel for applications including thermal conductivity sensing and chemi-resistive sensing.

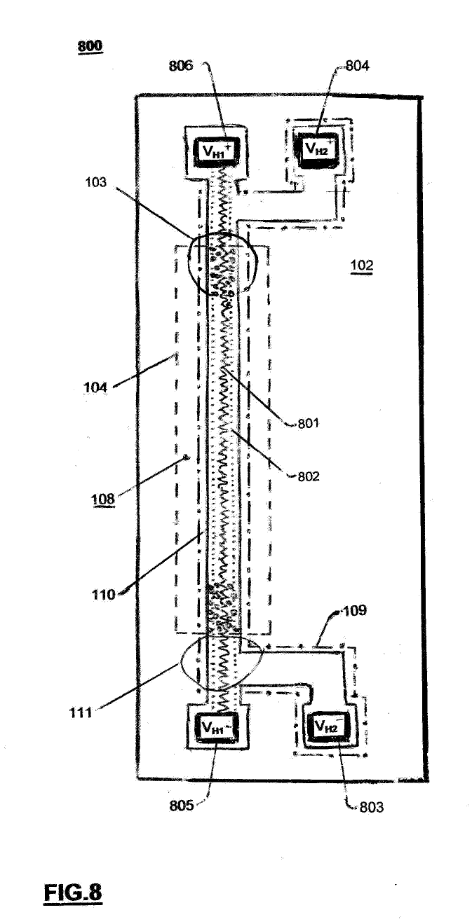

FIG. 8 depicts a plan view of the pixel comprised of two resistive thermal elements, each contacted separately. The micro-platform 110 is diffused to provide one thermal element and an overlying ALD film provides the second resistive element 801. The second thermal element 801 is electrically isolated from the micro-platform 110 by a dielectric film 802 such as silicon nitride. The micro-platform 110 is suspended over cavity 108 within boundary 104 surrounded by off-platform area 102. The micro-platform 110 is doped for high electrical conductivity throughout the area 109 including underneath bonding pads 803 and 804. The ALD resistive element is contacted with bonding pads 805 and 806

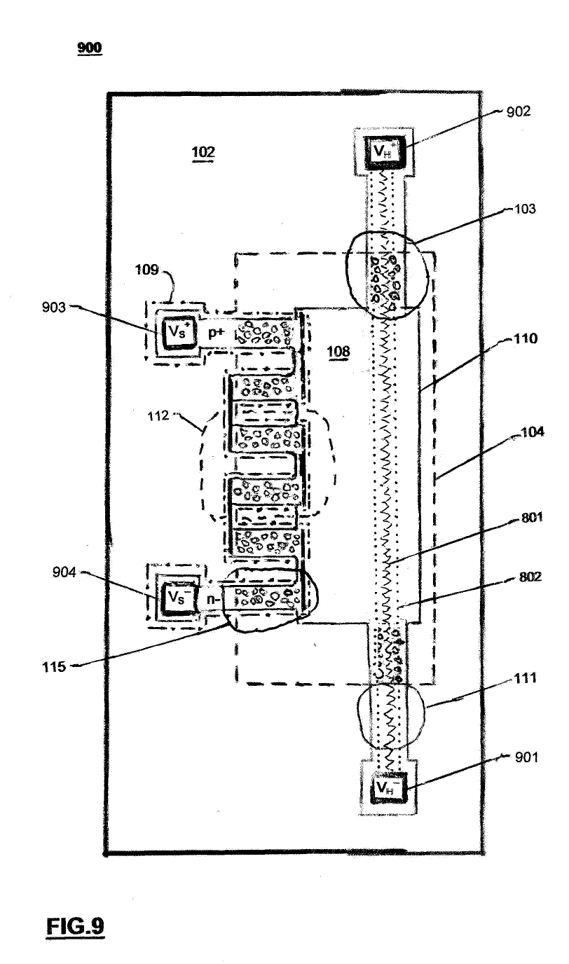

FIG. 9 depicts a pixel comprised of a single micro-platform 110 with two thermal elements. A first thermal element is comprised of a thin film ALD resistive thermal element 801, isolated micro-platform with an underlying dielectric film 802, and electrically connected with bonding pads 901/902. A second thermal element is comprised of series-connected thermoelectric devices 112, defined with diffusions 109 and connected with bonding pads 903,904. The resistive element is generally operated as a heater and/or thermistor and the thermoelectric element, in embodiments, is operated in a Seebeck sensor and/or Peltier cooler mode.

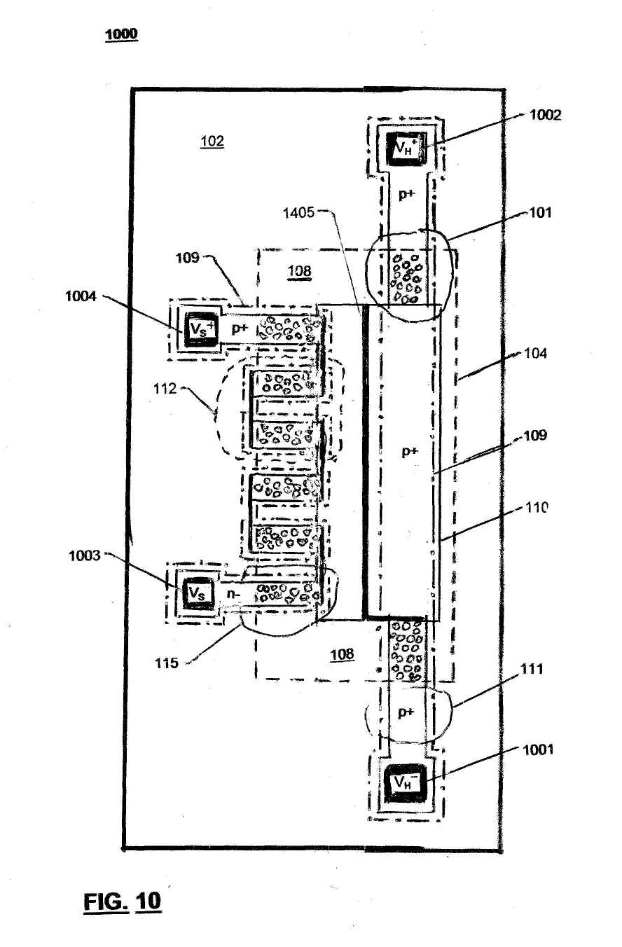

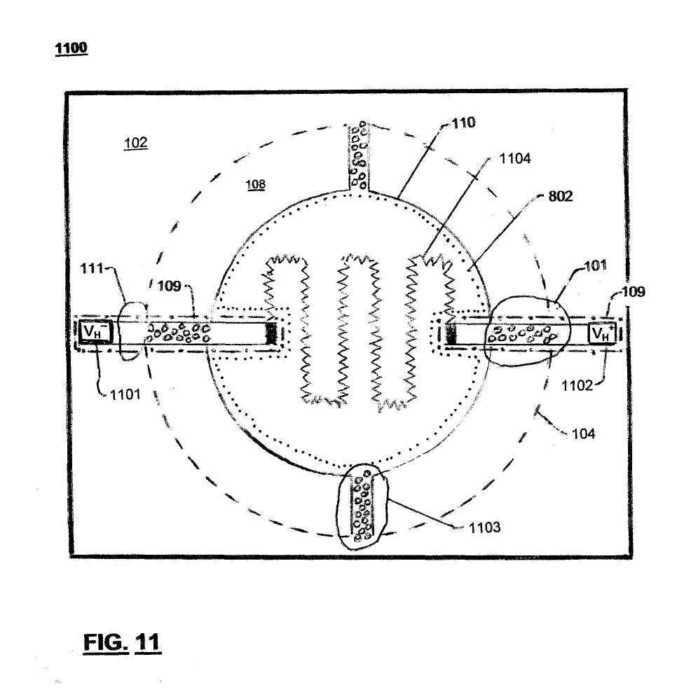

The pixel depicted in FIG. 10 is comprised of a single micro-platform 110 comprised of a resistive first thermal element defined by a diffusion 109 and a second thermal element comprised of a series connection of thermoelectric devices 112. The first thermal element is connected through nanowires 101 and support area 111 with bonding pads 1001,1002. The second thermal is connected though nanowires 115 with bond pads 1003,1004. An electrostatic trace 1405 provides electrical isolation between the two thermal elements and is typically a metal film connected to a thermal element at a single contact point. The micro-platform 110 is suspended over cavity 108 within boundary 104 surrounded by off-platform area 102.

The pixel depicted in FIG. 11 is comprised of micro-platform 110 in a circular format with a resistive first thermal element 1104 configured as a serpentine ALD film 1104 disposed over dielectric film 802 and connected through nanowires 109, 101 with contacting bonding pads 1101, 1102. The micro-platform is supported by four nanowires indicated as 101, 109 and 1103. The micro-platform 110 and nanowires 101 and 1103 are released over cavity 108 within surrounding support structure 102. In embodiments, a resistive second thermal element comprising the micro-platform active semiconductor region 110 is powered through nanowires 1103 to heat the micro-platform 110.

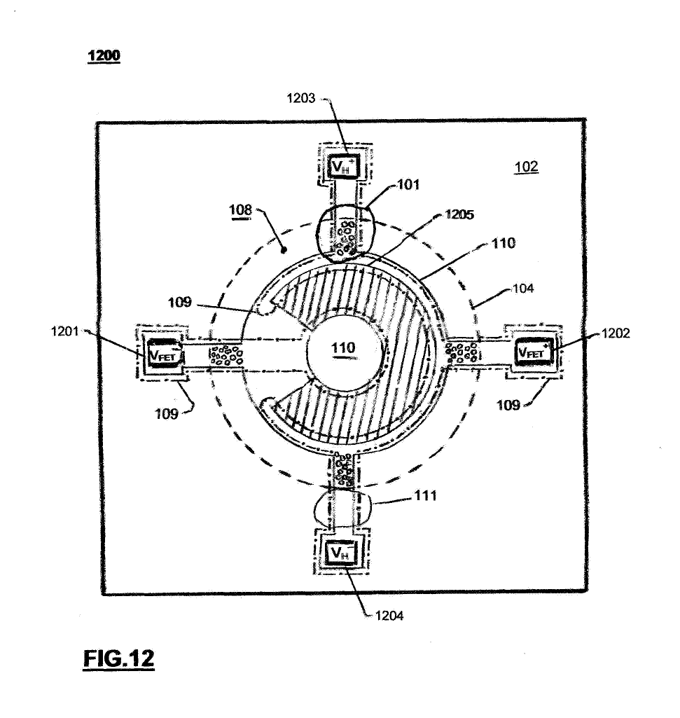

FIG. 12 depicts the pixel physically configured to provide a chem-FET sensor in a circular format comprised of a MOSFET passive thermal element. In some embodiments the gate dielectric 1205 is directed exposed with an analyte and in other embodiments an ALD catalytic film is patterned to cover the gate dielectric. In all embodiments of this pixel, an electric charge supplied from the analyte to the transistor gate changes the threshold voltage V_{T} of the MOSFET. In most embodiments, the ALD film is electrically floating. In some embodiments, the ALD film is electrically connected to the high resistivity micro-platform area to provide a path for draining charge from the gate area following an exposure. In other embodiments, a resistive path through diffused area 109 connecting with bonding pads 1203 and 1204 can be operated as a heater thermal element, to reset the MOSFET by outgassing and annealing out surface charge accumulations on the gate dielectric.

The MOSFET drain is defined by diffusion 109 with ohmic connection through a nanowire 101 to bonding pad 1201. The MOSFET source is defined by a separate diffusion 109 connected through nanowires 101, 111 with bonding pads 1202, 1203 and 1204. Readout of the chem-FET is obtained by sensing the transconductance of the MOSFET channel.

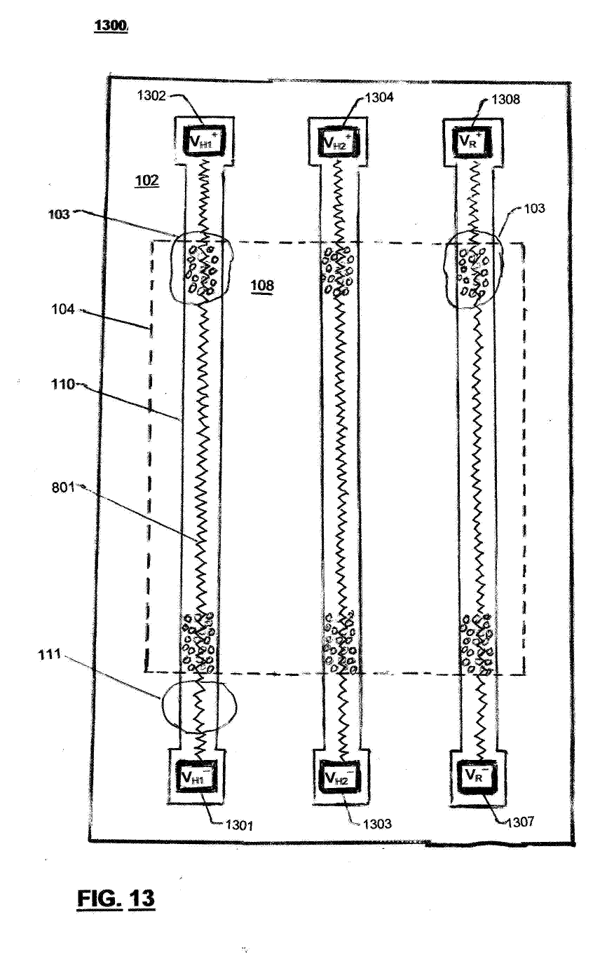

The pixel depicted in FIG. 13 is comprised of three isothermal micro-platforms 110, each providing a thermal element disposed over cavity 108 with perimeter 104 within a surrounding support platform 102. A patterned ALD thin film metal trace 801 comprises separate the heated portions of the three heater structures and is disposed directly on each micro-platform 110. Each resistive thermal element may be operated as a thermal heating element and/or as a passive thermistor thermal element. The micro-platforms 110 are suspended over cavity 108 within boundary 104 surrounded by off-platform support structure 102. The micro-platforms 110 are supported by nanowires 103 anchored on the surrounding substrate area 102. The three thermal platforms 110 and associated nanowires 103 are contacted through off-platform connections 111 with respective bonding pads 1301-1302, 1303-1304, and 1307-1308

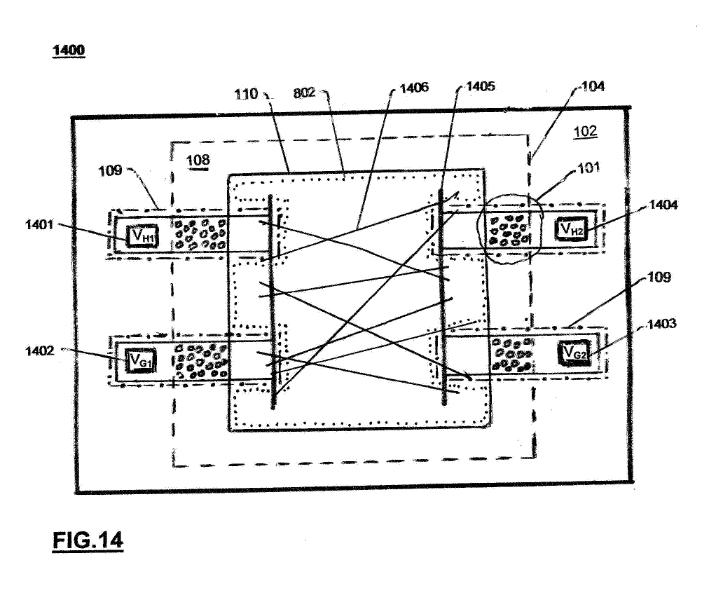

FIG. 14 depicts a pixel with a single micro-platform 110 in a rectangular format configured with spaced electrodes 1405 and a mesh 1406 of sheet graphene or nanotubes comprised of various selected materials including CNTs to provide a chemi-resistive sensor. The mesh 1406 provides an electrically conductive path between the two electrodes 1406 and is typically activated with additional metallorganic particles or film. The micro-platform 110 is partially covered with dielectric film 802 to provide increased electrical isolation from the galvanic path between bonding pads 1401/1402 and 1403/1404 used for sensor readout. In some embodiments, the galvanic connectivity between electrodes 1405 and bonding pads is provided by a layer of ALD metal disposed over the phononic layer or layers of nanowires 101. The micro-platform is supported by nanowires 101 over cavity 108 bounded by perimeter 104 within surrounding support platform 102. Sheet graphene, including graphene in rolled sheets, and nanotubes 1406 are disposed in electrical contact with the electrode traces 1405 and above dielectric film 802. In other embodiments not depicted in FIG. 14, a resistive thermal element is used to heat the micro-platform to increase chemi-resistive sensitivity of the mesh 1408 to an analyte and to provide a reset function.

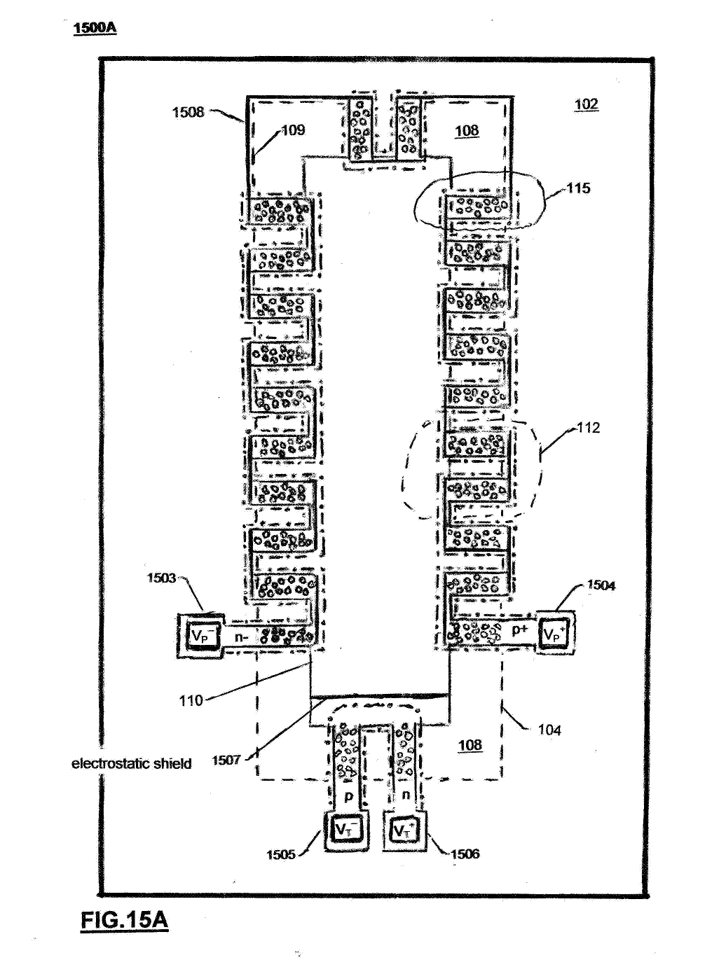

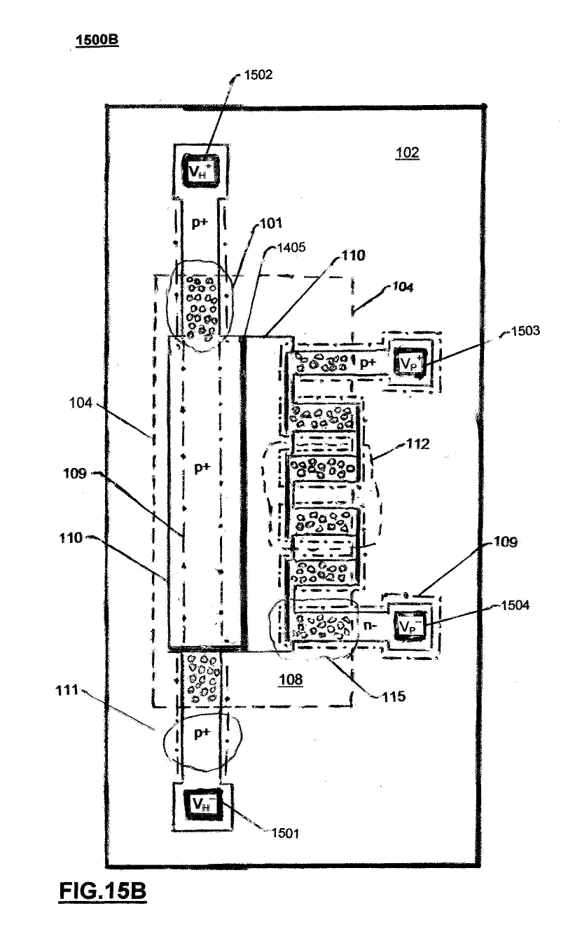

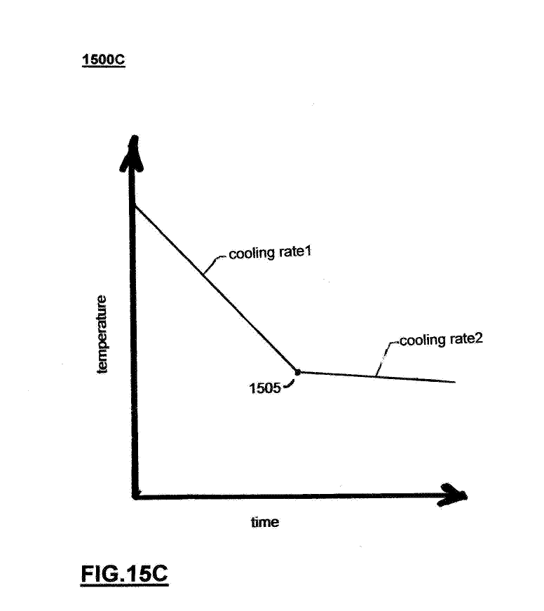

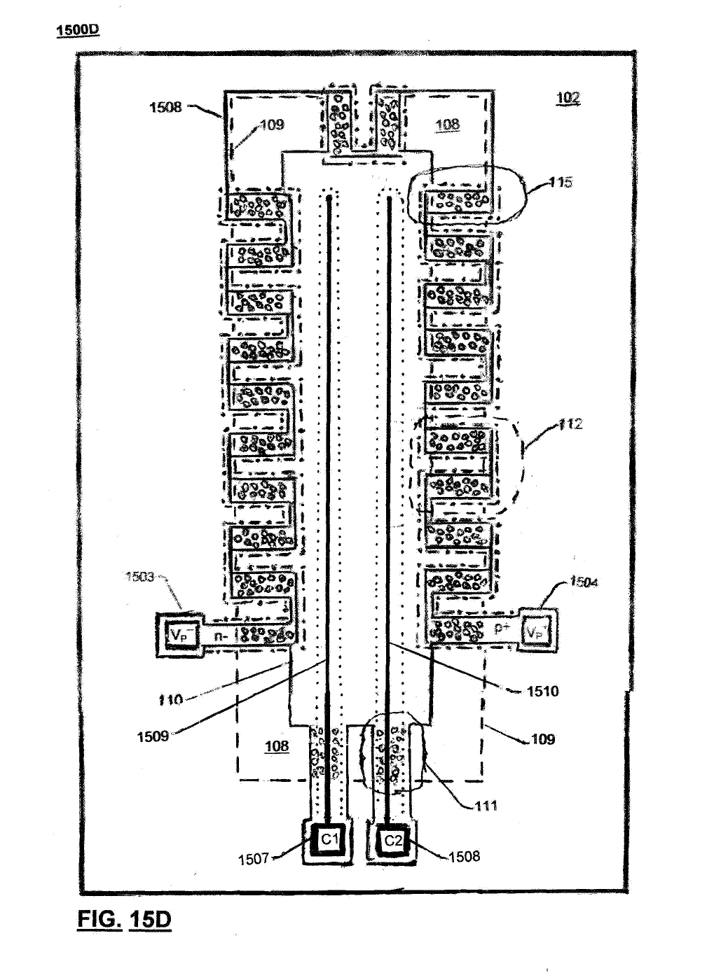

The pixel depicted in FIG. 15A is comprised of a single micro-platform 110 having two thermoelectric elements connected between bonding pads 1503, 1504 and 1505, 1506. The two thermoelectric elements of FIG. 15A are electrostatically shielded from each other with metal shield trace 1507. In the embodiments based on FIG. 15A, either thermoelectric thermal element may be operated as a Peltier cooling thermal element or a Seebeck temperature sensor thermal element. In another embodiment, the thermal element connected at 1505, 1506 is physically configured as a resistive thermal element operated as either a heater and/or a thermistor.

FIG. 15B depicts a single micro-platform 110 comprised of two thermal elements. A first thermal element is a thermoelectric array with nanowire devices 112 connected between bonding pads 1503 and 1504 and a diffused resistive thermal element connected between bonding pads 1501 and 1502. The first thermal element, in embodiments, is operated as a heater or a cooler. A second thermal element is a resistor 109 diffused into the micro-platform 110 connecting to bonding pads 1501 and 1502 through nanowires 101 and off-platform connections 111. The two thermal elements are electrostatically shielded from each other by metal trace 1405 having a single point ohmic connection into bonding pad 1501. The micro-platform 110 is suspended over cavity 108 having boundary 104 and surrounded by an off-platform support area 102.

FIG. 15D depicts a pixel physically configured with a single micro-platform 110 comprised of a single, meandered thermoelectric element 1508 and two electrically isolated electrodes 1509. The thermoelectric element 1508, comprised of devices 112 connected in series, is contacted with bonding pads 1503, 1604. The thermoelectric elements may be operated in either a Peltier or Seebeck mode. The two electrodes 1509, 1510 are disposed over a dielectric film on the micro-platform 110 and contacted with bonding pads 1507,1508. Readout from this pixel is obtained in embodiments by sensing the electric sensing field coupling with an analyte exposed within the area between electrodes 1509, 1510. This pixel embodiment is operated as a type of permittivity sensor is a type of permittivity sensor.

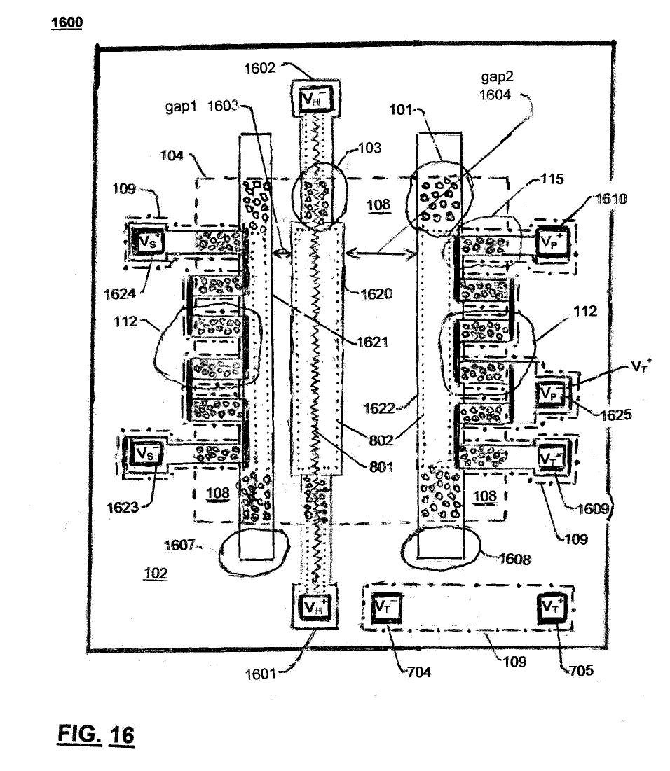

FIG. 16 depicts a pixel comprised of three micro-platforms 1620, 1621, 1622 each comprised of a thermal element. An ALD resistive element 801 disposed over a dielectric film 802 is supported by central micro-platform 1620. Thermal element 801 is contacted with bonding pads 1601, 1602. A first thermoelectric element is comprised of devices 112 in a series connection disposed on micro-platform 1621 is connected with bonding pads 1623,1624. Two additional thermoelectric elements connected with bonding pads 1610, 1625 and 1609, 1625 are disposed on micro-platform 1622. Each of the four thermoelectric elements, in embodiments, may be operated in either a Peltier or Seebeck mode. The three micro-platforms are suspended with nanowires over cavity 108 having a boundary 104. The nanowires are disposed partially disposed together with bonding pads on the off-platform region 102.

In embodiments, each pixel may be operated to provide a redundant sensor to provide an overall improved pixel sensor reliability or to provide for additional sensor data. The pixel may also be configured to provide a sensor which is not exposed to the analyte thereby providing a reference sensor for calibration purposes.

The pixels depicted in FIGS. 7-16 provide sensors disclosed further in the following examples:

### Example 1

### Pirani Pressure Gauge with Thermal Transport Sensing

In embodiments, when the analyte species and is known, the pixel may be physically configured and operated to provide a Pirani pressure gauge, sensitive to pressure of an analyte ranging from a vacuum pressure of 10 microTorr up to pressures in excess of 15 megaPa. In other embodiments, when pressure and temperature of the analyte are known, the pixel provides a means of identifying the analyte. In many embodiments, the pixel is configured with an off-platform environmental temperature sensor for calibration purposes. The transduction mechanism of the Pirani gauge in some embodiments is based on either a single thermal element dissipating heat by thermal transport into the analyte. In other embodiments the transduction mechanism is based on one heater element and one or more temperature sensors wherein a thermal transport is obtained from the heater element to the one or more sensor elements. In embodiments of “single platform” type, thermal transport into the exposed analyte provides a Pirani gauge by sensing the temperature of the isothermal micro-platform. In embodiments of “multi-platform” type, thermal transport through the analyte heats a temperature sensing element to provide a Pirani gauge.

In embodiments, the thermal element 706 of FIG. 7, the thermal element 1104 of FIG. 11 and a thermal element 801 of FIG. 13, each are operated with a single thermal element. In these pixel configurations, the single thermal element disposed on a micro-platform 110 provides a Pirani gauge wherein the heater and sensor function are provided by the same physical thermal element. In other embodiments, the pixel depicted in FIGS. 8 and 13 provide a Pirani gauge wherein a resistive heater and a thermister sensor are disposed on separate micro-platforms 110. In yet other embodiments, the pixel depicted in FIGS. 9, 10, 15A, 15B and 15D is configured with separate thermal elements disposed on a single micro-platform 110 to provide a Pirani gauge.

The pixel of FIG. 16, in another exemplary embodiment, provides a Pirani gauge of the “multi-platform” type. This embodiment is comprised of multiple thermoelectric sensor thermal elements providing an extended pressure sensing range. It is configured with three micro-platforms 1620, 1621 and 1622 wherein a resistive heater element is disposed at different distance gaps 1603, 1604 from adjacent temperature sensing elements. Multiple gaps 1603, 1604 provide a thermal transport through the analyte from the heater 801 to the sensing elements providing a Pirani gauge with extended pressure sensing range. A small gap1 1603 of less than 100 nm extends pressure sensing response far into the vacuum range. A larger gap2 1604 with dimension up to 1 um provides a useful gauge response into a higher pressure range. This pixel embodiment is comprised of a central resistive heater element 801 powered through connecting bonding pads 1601,1602 and two adjacent thermoelectric temperature sensors connected with bonding pads 1623, 1624 and 1609, 1610. The adjacent thermoelectric sensors are operated in the Seebeck mode.

In another Pirani gauge embodiment, the active thermal element is provided by operating one thermoelectric element to provide both a Peltier cooler and a Seebeck sensor. This is provided in the pixel of FIG. 16 with the thermoelectric device connected with bonding pads 1610, 1625 operated in the Peltier mode. Within this same structure, the thermoelectric device connected with bonding pads 1609, 1625 is operated in the Seebeck mode. This embodiment provides a Pirani gauge wherein the traditional heater thermal element is replaced by a Peltier cooling thermal element.

FIG. 15C illustrates the temperature transient obtained with operation of the pixel as a dew or frost-point sensor. In all embodiments of the Pirani pressure gauge, the dew or frost point temperature is provided by the temperature cooling temporal transient. This transient, sensed by a passive thermistor or Seebeck thermal element, undergoes an abrupt rate change from coolingrate1 to coolingrate2 at dew or frost point temperature 1505. This cooling transient provides a means for determining dew or frost point of an analyte.

### Example 2

### Chemi-Resistive Sensor

In embodiments, the pixel may be physically configured with an activation film, typically an ALD film, disposed over at least one thermal element to provide a chemi-resistive sensor. In embodiments, the activation film is a semiconductor affecting a change in the electrical conductivity of the thermal element as electrical charges resulting from a chemical reaction shift the Fermi level of the activation film when exposed to a particular analyte. In some embodiments, the thermal element is comprised of a catalyst, typically an ALD film or component within an activation film, wherein the catalyst affects the electrical conductivity of the thermal element when exposed to an analyte. In embodiments, the change in electrical conductivity of the thermal element provides a means for modulating the temperature of element when powered from an external current source. Activation films are typically metal oxide semiconductors, often wide bandgap semiconductors, and include one or more from a group including WO₃, TiO₂, In₂O₃, CeO₂ ZnO₂, MoS₂, In₂O₃, ZnO₂, CdS, SnO₂, and InₓSn_{y}O₂. In embodiments, semiconductor ALD films are doped with an impurity, for example a Pd impurity in SnO₂ providing sensitivity to CH₄ or a La impurity in ZnO providing a sensitivity to CO₂. Catalysts are typically comprised of one or more of Pd, Pt and Ag as ALD films or nanoparticles and flakes. Activation films are sensitive to one or more of analytes including H₂, CO, CO₂, NH₃, H₂S, NO, NO₂, BBr₃ H₂O₂, O₃ and volatile organic compounds.

The pixel is FIG. 13 is configured to provide a multi-platform chemi-resistive sensor wherein the three micro-platforms each provide sensitivity to one or more analytes. In embodiments, each micro-platform may be activated with the same activation material to provide a redundant sensor operated simultaneously or at different times. Alternatively, each micro-platform may be activated with a different activation material to provide a sensor with sensitivity to three different analytes.

In embodiments, the pixel of FIG. 14 is configured to provide a chemi-resistive sensor. Activation material added to the mesh 1406 increases the binding energy for components of the analyte due to molecular reactions resulting in a change in electrical conductance. In this embodiment, a mesh 1406 of graphene or nanotubes of various materials is disposed on the micro-platform 110 with electrical contact at electrodes 1405. Readout obtained through bonding pads 1401,1402 and 1403,1404.

In an exemplary embodiment, a mesh 1406 of CNTs is activated with boron and nitrogen providing a response on exposure to an analyte comprised of components such as NO₂, NH₃ and O₂. This chemical response is effected as B and N replace carbon atoms in the activated carbon structure. The chemi-resistive sensor embodiment of FIG. 14 may also be configured with a mesh 1406 of nanotubes comprised of selected materials including Cu₂O, SnO₂ and WO₃ in addition to CNTs.

The pixel of FIG. 15A is structured to provide a chemi-resistive sensor. The sensor is comprised of a first thermal element contacted with bonding pads 1505 and 1506 and operated as a heater. A second thermoelectric element 1508 is operated as a Seebeck thermoelectric sensor thermal element contacted with bonding pads 1503, 1504. In this embodiment, a patterned ALD surface film is disposed on and contacted to the micro-platform 110 to provide a parasitic resistive thermal element affecting the sensor voltage appearing at bonding pads 1503,1504. shunting response of the second thermal element. The voltage provided by the second thermoelectric element is modulated on exposure with the analyte to provide a chemi-resistor.

In most embodiments, the chemical reaction effecting the chemi-resistive sensor function is not exothermic. However, in some embodiments, the pixel may be physically configured to provide a chemi-resistor sensor of the pellistor type. In these embodiments, an appropriate ALD catalyst film is disposed on the micro-platform to provide a pellistor. In these embodiments, an exothermic chemical reaction occurs as the analyte reacts with the ALD catalytic film provides a further heating of the micro-platform which is sensed as an additional source of heat.

An exemplary pellistor is provided with the pixel depicted in FIG. 7 wherein the micro-platform 110 is covered with an ALD film, typically of Pd and or Pd, and heated. The heated ALD film itself is an activation material which reacts with hydrogen in the analyte increasing temperature micro-platform. Readout is obtained by sensing the resistance of thermal element the micro-platform 110 as a thermistor. This embodiment is typically used to detect explosive gases within an oxygen ambient.

### Example 3

### Chem-FET Gas Sensor

FIG. 12 depicts a chem-FET sensor comprised of an MOSFET wherein the transistor gate is sensitive to an analyte. In this sensor the transduction mechanism is based on electrical charge accumulating on a ALD gate film disposed on the gate dielectric or into the gate dielectric with exposure to an analyte. This electrical charge creates a mirror charge in the MOSFET channel which modulates the channel impedance by changing the Fermi level of the conducting channel. The chem-FET may be configured as an enhancement-type or depletion type of MOSFET depending on the channel conducting polarity, p- or n-type. Readout of the chem-FET is obtained typically by monitoring the impedance between the source-bonding pads 1202/1203/1204 and the drain bonding pad 1201. Reset of charge accumulating on or in the gate dielectric can be increased by heating the micro-platform 110 with external power supplied into bonding pads 1203,1204.

In a chem-FET embodiment, molecular hydrogen from an analyte is absorbed into an ALD film of Pd disposed on the gate dielectric 1205 where it undergoes a catalytic dissociation into atomic hydrogen (Ha) producing an electrical charge on the metallic film of gate dielectric 1205. This embodiment provides sensitivity for hydrogen-containing analytes such as NH₃. If instead, the gate electrode is a perforated film of Pt, the chem-FET provides an increased sensitivity to CO.

In some embodiments, an ALD film disposed on the gate dielectric of the chem-FET is connected to the high resistivity region of the micro-platform 110 to provide multi-megOhm bleeder resistance wherein the resistance drains charge from the transistor gate, and resets the chem-FET to an initial condition.

### Example 4

### Hygrometer with Thermal Conductivity Sensing

The pixel of FIGS. 15A and 15B in applications may be configured and operated to provide an absolute hygrometer based on a determination of the dew point and/or frost point temperature of a vapor such as humid air. The sensor transduction is based on the fact that water and ice have a much higher thermal conductivity and permittivity compared with the exposed humid vapor analyte. A sensor for humidity is provided. In embodiments, a hygrometer sensor is provided by monitoring the rate of a micro-platform cooling at the dew or frost point temperature due to increased thermal conductivity through the analyte. In embodiments wherein thermal conductivity is the transduction mechanism, the effect of ice or frost is monitored as it forms between thermal elements and also over a portion of supporting nanowires. In other embodiments, a hygrometer sensor is provided by monitoring the capacitance between capacitor electrodes disposed on a micro-platform as the permittivity increases with cooling through the dew or frost point temperature. In both of these embodiments, a micro-platform is cooled with Peltier thermoelectric thermal elements.

The exemplary embodiment of FIG. 15A provides an absolute hygrometer when configured with an active Peltier thermal element connected between bonding pads 1503-1504 and a passive Seebeck or thermistor sensing thermal element connecting bonding pads 1505-1506. In operation, the Peltier thermal element cycles temperature of the micro-platform 110 over a range that includes a dew or frost point of the analyte. In this embodiment, as water condenses or freezes from the analyte onto the cooled nanowires, a parasitic thermal conduction path that reduces the rate of thermoelectric cooling is created. Sensor readout is provided with the thermal sensing element connected with bonding pads 1505,1506.

Another embodiment providing an absolute hygrometer based on thermal conductivity of dew and ice is provided by the pixel of FIG. 15B. In this embodiment, the micro-platform 110 is comprised of an active Peltier thermal element with bonding pad connections 1503-1504 and a thermistor with bonding pad connections 1501 and 1502. As an exposed analyte is thermally cycled through a dew point or frost point, the temperature rate of the micro-platform cooling rate changes abruptly as monitored by the thermistor.

In another embodiment, the pixel depicted in FIG. 15D is configured as an absolute hygrometer with capacitance readout. The micro-platform 110 is cooled with the Peltier thermoelectric element powered through bonding pads 1503,1504. The micro-platform 110 and two electrodes 1509 and 1510 disposed in a parallel or interdigitated format are exposed to humid vapor. Capacitance between the two electrodes, measured with off-platform circuitry, changes abruptly as dew and/or frost forms on the micro-platform 110. In some embodiments, capacitance is measured with circuitry disposed on the off-platform area of the pixel. This application takes advantage of the fact that the dielectric constant within a film of water and ice on the micro-platform 110 is as large as 80 and the dielectric constant of is near 1.

In embodiments, the pixel configured as FIG. 16 is also operated to provide a an absolute hygrometer by cooling micro-platform 1622 through dew or frost point temperature wherein the thermoelectric device is operated as a Peltier cooler with power supplied through bonding pads 1610 and 1625. The temperature of cooling micro-platform 1622 is monitored by operating the thermoelectric device connected with bonding pads 1624,1609 in the Seebeck mode. As the micro-platform is cooled through dew or frost point temperature, dew and/or frost is deposited onto portions of the nanowires 115 and the rate of cooling slows. This change of cooling rate occurs at a temperature directly related to the humidity of the analyte permitting signal conditioning circuit connected at bonding pads 1609, 1625 to determine the analyte humidity.

FIG. 15C illustrates the dew and/or frost point temperature 1505 as determined by the change of cooling rates as the micro-platform 110 is cooled. The temperature cycling is illustrated as having different rates of temperature change above and below the frost or dew point temperature. FIG. 15C depicts the temperature of the micro-platform 110 as it is cooled through dew and/or frost temperature with the embodiment pixels of FIGS. 15A, 15B, 15D and 16.

### Example 5

### Capacitance Sensor with Controlled Platform Temperature

The sensing structure of FIG. 15D provides an electrical impedance sensor sensitive to the dielectric constant of an analyte exposed to the micro-platform 110 and electrodes 1507,1508. The dielectric constant is monitored by sensing the capacitance between electrodes 1509-1510. Temperature is controlled by a thermal element disposed on the micro-platform, and in this illustrative embodiment, the thermal element is a Peltier cooling element. In embodiments, signal conditioning circuitry bonded on or created within surrounding platform support 102 determines capacitance between electrodes 1507, 1508. In applications, at any specific temperature, the capacitance sensed with exposure to an analyte is sufficiently unique to a particular analyte to provide a useful identification or monitoring of the analyte. This pixel embodiment is suitable for monitoring an analyte having a relatively high dielectric constant.

### Example 6

### Integrated Biomedical Breath Analyzer and Spirometer

In an embodiment, the pixel of FIG. 13 is configured to provide an integrated capnometer and spirometer wherein the analyte is the expired breath of a human. In this pixel embodiment, the pixel of FIG. 13 is operated as a capnometer to measure the amount of CO₂ in expired breath of a patient and as a spirometer to measure the rate of breath expiration. A capnometer is provided by operating one of the micro-platforms as a chemi-resistive sensor activated with an ALD film of metallorganic semiconductor ZnO(La) or other material sensitive to CO₂. The electrical conductance for the resistive thermal element changes when exposed to the CO₂ component of expired breath.

For another biomedical breath sensing application, similar to the capnometer application, the chemi-resistive heater is activated with SnO₂, of various forms including nanotubes, to provide sensitivity to a breath component H₂. Chemi-resistive sensors of maximum sensitivity configured with thermoelectric sensing elements provide sensitivity to a range of breath components including ethanol and acetone.

In embodiments, a spirometer sensor is provided using all three micro-platforms 110 depicted in FIG. 13. In this embodiment, laminar breath flow comprising an analyte is directed over the pixel and in the plane of the pixel. The center thermal element contacted at 1303-1304, is operated as a resistive heater thermal element. The resulting thermal transport of breath over the pixel heats thermister elements 1301,1302 and 1307,1308 differentially. The differential temperature created between the two thermisters provides a means of monitoring the magnitude and direction of breath flow rate across the pixel. I

In another embodiment, the pixel of FIG. 16 may be operated as a breath analyzer and spirometer. The central micro-platform 1620 is configured and operated as a chemi-resistive sensor for chemical analysis of a breath component. FIG. 16 provides a spirometer wherein the central micro-platform 1620 is operated as heat source and the temperature differential due to breath flow across the pixel is measured with micro-platforms 1621,1622 operated as Seebeck sensors. Flow rate of the analyte is monitored with the gap1 and gap2 increased to reduce pixel sensitivity to barometric pressure.

### Example 7

### Pixel Configured as a Micro Weather Station

The thermal pixel of FIG. 16 with its three isothermal micro-platforms can be configured to provide a micro weather station. In these embodiments, the analyte is environmental air. In embodiments, the pixel comprised of three micro-platforms 1620, 1621 and 1622 can be interfaced with appropriate signal conditioning and control circuitry to provide a chemi-resistive sensor, a hygrometer/humidity sensor, a barometer, a windspeed sensor and an environmental thermometer. The three platforms are disposed over cavity 108 with boundary perimeter 104 within surrounding support platform 102.

The chemi-resistive sensing function is provided with activating the thin film metal trace 801 comprised of an appropriate ALD film sensitive to a selected analyte. The chemi-resistive sensor structure within the pixel is comprised of micro-platform 1620, insulating dielectric film 802 with ALD metal trace 801 connected to bonding pads 1601-1602 through nanowires 103. Incremental changes in the electrical conductivity of the activated metal trace 801 provide a response unique to an analyte of interest comprised of an component of interest such as NOx or CO₂.

The hygrometer sensor function is provided with the pixel of FIG. 16 as detailed in EXAMPLE 4. In this embodiment, humidity is sensed with micro-platform 1622 operated in the Peltier mode and without heating of micro-platform 1620.

The barometer function is provided by monitoring thermal transport through the analyte from the heated central platform 1620 to adjacent thermoelectric structures disposed on platform 1621. The thermoelectric thermoelectric structure 1621 is operated as a Seebeck temperature sensor. The analyte exposed to the pixel modulates the thermal transport from the central heater micro-platform 1620 onto micro-platform 1621 across gap1 1603. Heat transport across gap1 is sensitive to the mean free path of air molecules which is directly proportional to analyte air pressure. Barometric pressure changes provide an incremental change in heating via thermal transport to micro-platform 1621. For operation as a barometer, the array of thermoelectric devices 112 connected with bonding pads 1623, 1624 are operated in a passive Seebeck temperature sensing mode with heat provided from micro-platform 1620. A value of barometric pressure is unique for each Seebeck voltage reading at any environmental temperature. The sensitivity of the thermal sensor of micro-platform 1621 to air flow over the pixel is minimal for gap1 dimensions of less than 100 nm. Advantageously, the sensitivity gauge factor the barometer is maximized for gap1 dimensions of less than 100 nm.

A wind speed sensor is provided by monitoring the thermal transport over an increased gap2 of 100 to 500 nm wherein sensitivity to barometric pressure is minimal. Wind speed is monitored by operating the thermoelectric array of micro-platform 1622 as a Peltier temperature sensor. Air flow over the heated micro-platform 1620 and onto micro-platform 1622 effects significant modulation of the micro-platform 1622 temperature. The Seebeck sensor voltage at bonding pads 1609, 1610 provide a measure of positive 1-dimensional speed speed. Seebeck sensor is calibrated against environmental temperature using thermistor diffusion 109 connected with bonding pads 704 and 705. The wind speed sensor is calibrated at temperatures in a laboratory windtunnel.

The environmental temperature sensor is provided by a reference thermistor comprising diffused p-type region 109 contacted by bonding pads 704 and 705. The surrounding support platform 102 is maintained at environmental temperature.

It is to be understood that although the disclosure teaches many examples of embodiments in accordance with the present teachings, many additional variations of invention can easily be devised by those skilled in the art after reading this disclosure. As a consequence, the scope of the present invention is to be determined by the following claims.

What is claimed is:

1. A thermal pixel comprised of a micro-platform supported by a plurality of nanowires, wherein each nanowire is partially disposed on both the micro-platform and an off-platform substrate region, the off-platform substrate region surrounding the micro-platform, and the pixel further comprised of a sensing structure having at least one thermal element, wherein the at least one thermal element is disposed on the micro-platform and exposed to a gas or vapor analyte, and further wherein:
one or more of the plurality of nanowires is physically configured with one or more first layers, the first layers comprised of phononic scattering nanostructures and/or phononic resonant nanostructures, the nanostructures providing a reduction in the ratio of thermal conductivity to electrical conductivity;
the one or more of the plurality of nanowires provides a reduction in the mean free path for at least some heat conducting phonons;
the electrical impedance of the at least one thermal element is affected by exposure with the analyte, and
the thermal pixel providing a means for identifying and/or monitoring one or more chemical or physical characteristics of the analyte.

2. The pixel of claim 1 further wherein the one or more first layers of phononic nanostructures is further comprised of one or more of randomly disposed and/or periodic array of holes, pillars, plugs, cavities, surface structures, implanted elemental species, and embedded particulates.

3. The pixel of claim 1 further wherein the one or more first layers is physically configured as a phononic crystal having a phononic bandgap, and further wherein the phononic crystal substantially blocks heat transporting phonons within a selected range of frequencies.

4. The pixel of claim 1 further wherein the one or more first layers is a semiconductor selected from a group including one or more of silicon, germanium, silicon-germanium, zinc oxide, titanium oxide, gallium arsenide, gallium nitride, indium phosphide, silicon carbide, Bi₂Te₃, Bi₂Se₃, CoSb₃, Sb₂Te₄, La₃Te₄ ZnS, CdS, SnSe, and alloys thereof.

5. The pixel of claim 1 further wherein the one or more of the plurality of nanowires is further comprised of a second layer providing an increased electrical conductivity, the second layer being comprised of one or more of a metal selected from the group consisting of Pt, W, Pd, NiCr, Cu, Ti, Mo, and Al.

6. The pixel of claim 1 further wherein the one or more of the plurality of nanowires is comprised of a third layer providing an electrical isolation and/or a controlled mechanical stress, the third layer being comprised of a dielectric selected from a group including silicon nitride, silicon oxynitride, aluminum oxide, and silicon dioxide.

7. The pixel of claim 1 further wherein at least one thermal element provides a means for controlling temperature of the micro-platform, the at least one thermal element being comprised of a resistive heater and/or a Peltier thermoelectric cooler.

8. The pixel of claim 1 further wherein at least one thermal element is a resistive heater providing a means for outgassing and/or thermal reset of structures disposed on the micro-platform.

9. The pixel of claim 1 wherein at least one thermal element is a temperature sensor disposed on the micro-platform, the one thermal element selected from a group including a thermistor, MOSFET, bandgap diode, and a Seebeck thermocouple.

10. The pixel of claim 1 further wherein the at least one thermal element is comprised of one or more of a metal film, semiconductor film including nanotube structure, and a semiconductor device

11. The pixel of claim 1 further wherein one or more thermal elements is physically configured to provide an active thermal element and/or a passive thermal element.

12. The pixel of claim 1 further comprised of a chemi-resistive sensor having a sensitivity to a chemical reaction effected by exposure with the gas or vapor analyte, and wherein the chemi-resistive sensor is physically configured with the at least one thermal element having an activation material.

13. The chemi-resistive sensor of claim 12 wherein a thermal element is comprised of a catalyst providing an increased sensitivity to the analyte, and wherein the catalyst is selected from the group comprised of one or more of Pd, Pt, and Ag.

14. The chemi-resistive sensor of claim 12 wherein the analyte is selected from a group that includes of one or more of H₂, H₂O, Cl₂, CO, CO₂, NH₃, H₂S, NH₃, NO, NO₂, BBr₃, H₂O₂, O₃, SiH₄, and volatile organic compounds.

15. The pixel of claim 1 further comprised of a chem-FET sensor having sensitivity to a chemical reaction effected by exposure with the analyte, the chem-FET comprised of a MOSFET having a gate-electrode or gate-dielectric directly exposed to the analyte.

16. The pixel of claim 1 further comprised of a pressure gauge providing a means for sensing pressure of the analyte wherein the electrical impedance of the one or more thermal elements is affected by thermal energy transport within the analyte.

17. The pixel of claim 1 further comprised of a hygrometer sensor providing a means for determining the humidity of the analyte, wherein an electrical impedance of one or more thermal elements is affected by a dew or frost point temperature and/or thermal conductivity of the analyte.

18. The pixel of claim 1 further comprised of at least one sensor selected from the group consisting of capnometer, spirometer, capacitance sensor, miniature weather station, redundant sensor, reference calibration sensor, sensor with sensitivity to multiple analytes, and sensor with extended and/or complementing sensitivity range.

19. The pixel of claim 1 wherein the micro-platform and the plurality of nanowires are provided within particular layers of an SOI wafer.

20. A method for identifying or monitoring one or more chemical and/or physical characteristics of the analyte using a pixel according to claim 1, the method comprising:
(i) a first measurement of electrical signals affected by the electrical impedance of a thermal pixel exposed to one or more of reference gas or vapor analytes having a known first characteristic.
(ii) a second measurement of electrical signals affected by the electrical impedance of the thermal pixel exposed to an analyte of interest, and
(iii) wherein the first and second measurements comprise a sensor signal database providing the means for identifying and/or monitoring the one or more chemical or physical characteristics of the analyte.
